(19) United States
(12) Patent Application Publication
(10) Pub. No.: US 2026/0169374 A1
(43) Pub. Date: Jun. 18, 2026

(54) PATTERN REPAIR METHOD, PATTERN REPAIR DEVICE, AND RECORDING MEDIUM

(71) Applicant: Kioxia Corporation, Tokyo (JP)

(72) Inventors: Takeharu MOTOKAWA, Zushi Kanagawa (JP); Katsuyoshi KODERA, Yokohama Kanagawa (JP); Yuto TAMENO, Yokohama Kanagawa (JP); Keiko MORISHITA, Yokohama Kanagawa (JP)

(73) Assignee: Kioxia Corporation, Tokyo (JP)

(21) Appl. No.: 19/323,236

(22) Filed: Sep. 9, 2025

(30) Foreign Application Priority Data
Dec. 18, 2024 (JP) 2024-221609

(51) Int. Cl. G03F 1/72; G03F 7/00

(52) U.S. Cl. CPC G03F 1/72; G03F 7/7065; G03F 7/70666

(57) ABSTRACT

According to an embodiment, a pattern repair method includes acquiring information about a defect in a pattern of a light shielding film in a photomask and acquiring respective optical properties of the light shielding film and a repair film for repairing the defect. The method includes determining a film thickness of the repair film based on the optical properties. The method includes acquiring design information of a candidate of a pattern of the repair film. The design information includes film thickness information. The method includes calculating an exposure margin for each piece of design information. The method includes forming the repair film in the photomask in accordance with a piece of design information corresponding to the exposure margin exceeding a threshold value.

### CROSS-REFERENCE TO RELATED APPLICATIONS

This application is based upon and claims the benefit of priority from Japanese Patent Application No. 2024-221609, filed on Dec. 18, 2024, the entire contents of which are incorporated herein by reference.

### FIELD

Embodiments described herein relate generally to a pattern repair method, a pattern repair device, and a recording medium.

### BACKGROUND

In a lithography operation of a semiconductor device, light emitted from an exposure device is diffracted by a pattern of a photomask, and the diffracted light interferes on a semiconductor substrate, thereby forming an optical image.

The pattern of the photomask is configured of a light shielding film. When a defect is found in the pattern in a manufacturing operation of the photomask, the defect is repaired by a repair film.

However, optical properties of the repair film and optical properties of the light shielding film may not be the same. Therefore, the repair film formed in the photomask may change an optical image to be formed on the semiconductor substrate.

### BRIEF DESCRIPTION OF THE DRAWINGS

FIG. 1Aa, 1Ab, 1Ba, and 1Bb are schematic diagrams illustrating a pattern defect according to an embodiment;

FIG. 2 is a diagram illustrating an outline of various processes executed in a pattern repair system according to the embodiment;

FIG. 3 is a diagram illustrating an example of a configuration of the pattern repair system according to the embodiment;

FIG. 4 is a diagram illustrating an example of a hardware configuration of a repair pattern generation unit according to the embodiment;

FIG. 5 is a flowchart illustrating an example of a procedure of a pattern repair process according to the embodiment;

FIG. 6Aa, 6Ab, 6Ba, and 6Bb are diagrams illustrating an example of design information of a candidate of a pattern of a repair film according to the embodiment;

FIG. 7 is a diagram illustrating a procedure of a process of a calculation lithography program according to the embodiment;

FIG. 8 is a diagram illustrating an example of a calculation result of an exposure margin according to the embodiment;

FIG. 9 is a diagram illustrating another example of the calculation result of the exposure margin according to the embodiment; and

FIGS. 10A and 10B are diagrams illustrating another example of design information of a candidate of a pattern of a repair film according to the embodiment.

### DETAILED DESCRIPTION

A pattern repair method according to an embodiment includes executing first to sixth operations. The first operation includes acquiring information about a defect in a pattern of a light shielding film in a photomask, and acquiring optical properties of the light shielding film and optical properties of a repair film for repairing the defect. The second operation includes determining a film thickness of the repair film based on the optical properties of the light shielding film and the optical properties of the repair film. The third operation includes acquiring one or more pieces of design information indicating a dimension and a shape of a candidate of a pattern of the repair film. The one or more pieces of design information include film thickness information indicating the film thickness of the repair film. The fourth operation includes calculating an exposure margin for each of the one or more pieces of design information by electromagnetic field calculation using the film thickness information of the repair film. The fifth operation includes selecting a piece of design information corresponding to the exposure margin exceeding a threshold value from among the one or more pieces of design information. The sixth operation includes forming the repair film in the photomask in accordance with the selected piece of design information.

Hereinafter, a pattern repair method, a pattern repair device, and a recording medium according to embodiments are described in detail with reference to the accompanying drawings. Note that the present invention is not limited by the embodiments.

In a manufacturing operation of a photomask, a desired pattern is drawn with an electron beam on a resist film on a glass substrate such as quartz glass on which a light shielding film is formed, and development of the resist film and etching of the light shielding film are performed. As a result, a transfer pattern configured of the light shielding film is formed on the glass substrate.

When a pattern defect is detected by a defect inspection device, the detected pattern defect is repaired by the repair film. Thereafter, cleaning and quality checking are performed, and thereby a photomask is completed, in which repair of pattern defects is guaranteed.

However, the optical properties of the repair film may be different from the optical properties of the light shielding film. By adjusting a formation amount of the repair film such that the optical properties thereof are substantially equal to those of a part of the light shielding film, the film thickness of the repair film may differ from the film thickness of the light shielding film. Such a difference in film thickness in the transfer pattern may cause a difference in amplitude and phase of diffracted light and may cause a difference in an optical image formed on the semiconductor substrate as a so-called three-dimensional mask effect.

The three-dimensional mask effect includes deviation of the optical image of the transfer pattern having a three-dimensional structure from an ideal optical image. The three-dimensional mask effect becomes apparent when a fine pattern is formed such that a dimension of the pattern formed on the semiconductor substrate is equal to or less than a wavelength of the exposure device.

For the manufacturing operation of the photomask, an inverse lithography technology (ILT) is used for designing the pattern of the photomask by solving an inverse problem with the optical image formed on the semiconductor substrate as the ideal optical image. Therefore, if the optical image formed on the semiconductor substrate is different from the ideal optical image, the accuracy of pattern design may be deteriorated.

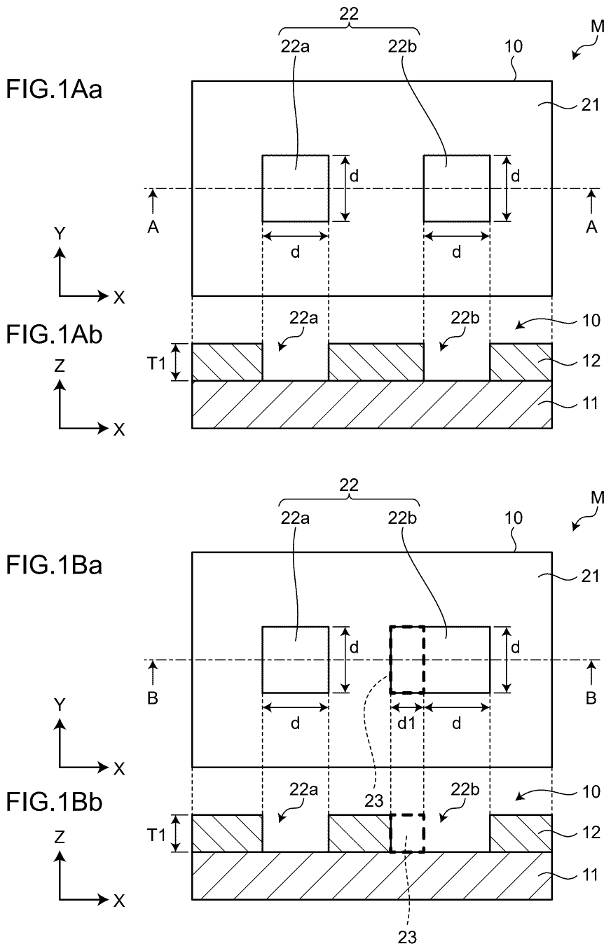

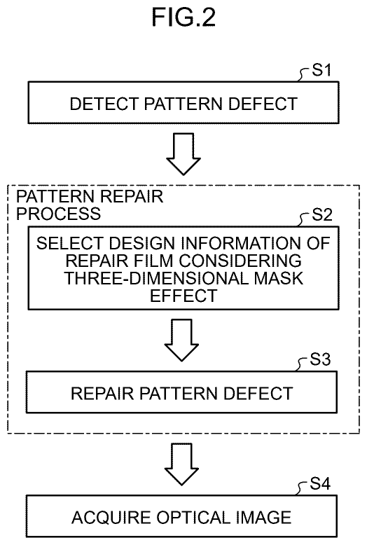

For solving the above-noted problem, the pattern repair system according to the embodiment performs various processes illustrated in FIG. 2. Prior to FIG. 2, a pattern defect to be repaired in the present embodiment will be described with reference to FIG. 1Aa, 1Ab, 1Ba, and 1Bb.

Note that, in the present specification, predetermined directions along a surface of the glass substrate are referred to as an X direction and a Y direction. The X direction and the Y direction are orthogonal to each other. A direction intersecting the X and Y directions is defined as a Z direction. An orientation of an arrow in each direction is defined as a positive direction, and the opposite direction is defined as a negative direction.

FIG. 1Aa, 1Ab, 1Ba, and 1Bb are schematic diagrams illustrating a pattern defect 23 according to the embodiment. FIG. 1Aa and 1Ab illustrate a transfer pattern 10 not including the pattern defect 23 as comparison targets of FIG. 1Ba and 1Bb, and FIG. 1Ba and 1Bb illustrate a transfer pattern 10 including the pattern defect 23. FIG. 1Aa and 1Ba are plan views of a photomask M including transfer pattern 10, and FIG. 1Ab and 1Bb are cross-sectional views taken along each of lines AA and BB in FIG. 1Aa and 1Ba.

As illustrated in FIG. 1Aa to 1Bb, the transfer pattern 10 of the photomask M is formed on a glass substrate 11. The glass substrate 11 is configured of, for example, quartz glass or the like and is formed in a rectangular shape of 6 square inches. The transfer pattern 10 includes a light shielding forming part 21 configured of a light shielding film 12 and light transmitting parts 22 (22a and 22b) formed by exposing the glass substrate 11.

The light shielding film 12 is a film having a lower transmittance of exposure light than the glass substrate 11. The transmittance is, for example, 6%. The light shielding film 12 is, for example, a silicon nitride film or a molybdenum silicide film. The light shielding film 12 is also referred to as a phase shift film and has a property of inverting a phase of transmitted light. In the present embodiment, a film thickness of the light shielding film 12 in the light shielding forming part 21 is referred to as “T1”.

As illustrated in FIG. 1Aa and 1Ab, the light transmitting parts 22a and 22b arranged along the X direction are each formed in a square shape having a side length of “d”. Each of the light transmitting parts 22a and 22b is surrounded by the light shielding forming part 21. Thus, an optical image formed by the transfer pattern 10 becomes a hole pattern or a dot pattern.

Meanwhile, in FIG. 1Ba and 1Bb, the light shielding forming part 21 adjacent to an end part of the light transmitting part 22b on a negative X direction side is partly missing by a length “d1” toward the negative X direction side. The light transmitting part 22b has a rectangular shape having long sides along the X direction. Thus, the light transmitting part 22b in FIG. 1Ba and 1Bb is in a state where the dimension in the X direction is excessive (large) by “d1” compared to the target dimension “d”.

In the present embodiment, hereinafter, a defective part of the light shielding forming part 21 is referred to as the pattern defect 23. The pattern defect 23 is part of the light shielding forming part 21 adjacent to the end part of the light transmitting part 22b on the negative X direction side, and is missing by the length “d1” toward the negative X direction side. The pattern defect 23 is an example of the pattern defect to be repaired.

In the example of FIG. 1Aa and 1Ab, the light transmitting parts 22 (22a and 22b) are each formed in a square shape (rectangular shape), but the shapes of the light transmitting parts 22 are not limited thereto. In one example, the light transmitting part 22 may be formed in a groove shape extending in the X direction or the Y direction.

FIG. 2 is a diagram illustrating an outline of various processes executed in a pattern repair system 1 according to the embodiment.

As illustrated in FIG. 2, the pattern repair system 1 of the present embodiment performs processing including a detection process of the pattern defect 23 (step S1), a selection process of design information of a repair film considering a three-dimensional mask effect (step S2), a repair process of the pattern defect 23 based on the design information (step S3), and an acquisition process of an optical image after repair (step S4).

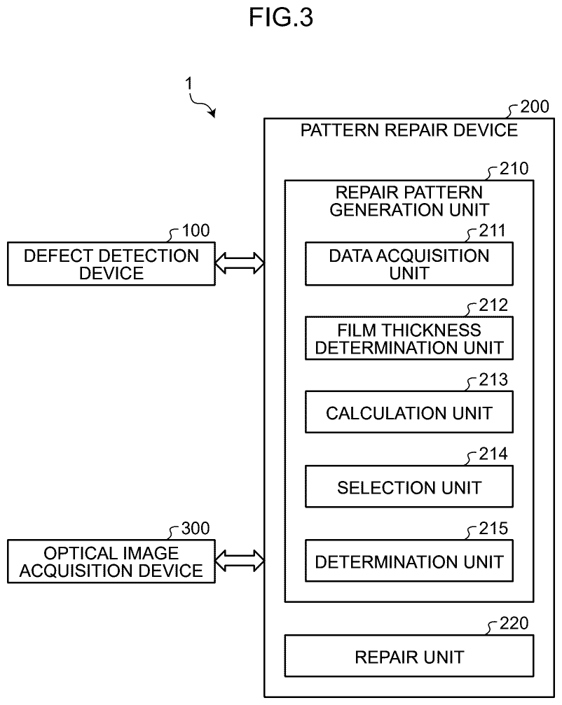

The process of step S1 is a process of capturing an image of the transfer pattern 10 formed in the photomask M and detecting the pattern defect 23 from the captured image of the transfer pattern 10. The process in step S1 is performed by a defect detection device 100 in FIG. 3 described below.

The process of step S2 is a process of performing electromagnetic field calculation considering the three-dimensional mask effect and selecting suitable design information from design information of one or more candidates for the pattern of the repair film based on the calculation result. Considering the three-dimensional mask effect in the electromagnetic field calculation means including film thickness information indicating a film thickness of the pattern of the repair film in the electromagnetic field calculation.

The process of step S3 is a process of forming the repair film on the transfer pattern 10 in accordance with the selected design information of the pattern of the repair film. The process in steps S2 to S3 is performed in a pattern repair device 200 in FIG. 3. Hereinafter, the process of steps S2 to S3 may be collectively referred to as a pattern repair process.

The process of step S4 is a process of acquiring an optical image of the transfer pattern 10 on which the repair film is formed. The process in step S4 is mainly performed in an optical image acquisition device 300 in FIG. 3.

FIG. 3 is a diagram illustrating an example of a configuration of the pattern repair system 1 according to the embodiment.

As illustrated in FIG. 3, the pattern repair system 1 according to the embodiment includes the defect detection device 100, the pattern repair device 200, and the optical image acquisition device 300. The defect detection device 100, the pattern repair device 200, and the optical image acquisition device 300 are communicably connected to each other.

The defect detection device 100 is, for example, a scanning electron microscope (SEM). The defect detection device 100 captures the image of the transfer pattern 10. The defect detection device 100 detects the pattern defect 23 from the image of the transfer pattern 10. Detection of the pattern defect 23 can be performed, for example, by comparison with design data or comparison of images of adjacent transfer patterns 10.

The pattern repair device 200 includes a repair pattern generation unit 210 and a repair unit 220.

Although details are described below, the repair pattern generation unit 210 is configured as, for example, a computer including a hardware processor such as a central processing unit (CPU) and a memory. The repair pattern generation unit 210 includes a data acquisition unit 211, a film thickness determination unit 212, a calculation unit 213, a selection unit 214, and a determination unit 215.

The data acquisition unit 211 acquires the image of the pattern defect 23 detected by the defect detection device 100. The image of the pattern defect 23 is an example of information about the pattern defect 23. The data acquisition unit 211 also acquires an image of a reference pattern.

The reference pattern is the transfer pattern 10 in which the pattern defect 23 is not formed. The data acquisition unit 211 may acquire the image of the reference pattern from the image captured by the defect detection device 100 or may acquire the image of the reference pattern from the memory of the repair pattern generation unit 210 or the like.

The data acquisition unit 211 acquires optical properties of the light shielding film 12 configuring the light shielding forming part 21 and optical properties of the repair film. The optical properties include at least one of a light transmittance in a predetermined wavelength or a phase difference. The data acquisition unit 211 acquires the optical properties of the light shielding film 12 and the repair film from the memory of the repair pattern generation unit 210 or the like.

As a film type of the repair film, for example, a multilayer film in which a chromium film is stacked on a TEOS film is used. However, the film type of the repair film is not limited thereto. The film type of the repair film can be changed freely.

The data acquisition unit 211 also acquires design information of at least one or more candidates of a pattern of a repair film to be formed on the transfer pattern 10 for repairing the pattern defect 23 based on the image of the pattern defect 23 and the image of the reference pattern. The design information indicates a dimension and a shape of the pattern of the repair film and includes film thickness information indicating the film thickness of the pattern of the repair film.

The data acquisition unit 211 acquires the design information of the candidate of the pattern of the repair film as follows. For example, the data acquisition unit 211 acquires information other than the film thickness information in the design information of the candidate of the pattern of the repair film using a learned model that outputs design information of a suitable pattern of the repair film upon inputting the image of the pattern defect 23. Then, the data acquisition unit 211 acquires the film thickness information in the design information of the candidate of the pattern of the repair film from the film thickness determination unit 212 described below. Note that the data acquisition unit 211 may acquire the film thickness information using a learned model.

Alternatively, the data acquisition unit 211 may acquire the design information of the candidate of the pattern of the repair film including the film thickness information based on information input by a user via an input unit described below.

The data acquisition unit 211 also acquires information about an index for determining whether an influence occurs on the optical image described below. For example, the data acquisition unit 211 acquires such information based on the information input by the user via the input unit.

The film thickness determination unit 212 determines the film thickness of the repair film based on the optical properties of the light shielding film 12 and the repair film. Specifically, the film thickness determination unit 212 determines the film thickness of the repair film such that the optical properties of the candidate of the pattern of the repair film are substantially equal to the optical properties of the light shielding film 12 in the light shielding forming part 21. The determined film thickness is common to one or more candidates of the pattern of the repair film acquired by the data acquisition unit 211. The film thickness information is transmitted to the data acquisition unit 211.

The calculation unit 213 uses the electromagnetic field calculation and calculates an exposure margin based on each piece of design information of one or more candidates of the pattern of the repair film. Specifically, the calculation unit 213 calculates the exposure margin for the optical image of the transfer pattern 10 assuming that the candidates of the pattern of the repair film for which the dimensions and the shapes are identified by the design information are formed on the transfer pattern 10. The calculation unit 213 also calculates an exposure margin in the reference pattern for comparison.

As described above, the design information of the candidate of the pattern of the repair film includes the film thickness information of the pattern of the repair film. The calculation unit 213 performs electromagnetic field calculation using the film thickness information of the pattern of the repair film. As a result, it is possible to obtain the exposure margins considering the film thicknesses of the candidates of the pattern of the repair film.

The exposure margin is an index indicating an allowable range of variations in exposure conditions in a lithography operation, a step on a semiconductor substrate, and the like. The exposure margin includes a percentage at which a pattern having a desired dimension is obtained on the semiconductor substrate. Specifically, the exposure margin includes an allowable range of a dose for forming a pattern (optical image) having a target dimension on the semiconductor substrate and an allowable range of a focus value.

Ideally, the exposure margin for the reference pattern is equal to the exposure margin based on each piece of design information of the candidate of the pattern of the repair film. This is because, when the exposure margin based on the candidate of the pattern of the repair film decreases compared to the exposure margin for the reference pattern, a light intensity distribution by the repair film is deteriorated, namely, an influence occurs on the optical image. In the present embodiment, determination as to whether an influence occurs on the optical image is performed by using the exposure margin as an index. Specifically, the determination is performed by using, as the index, at least one of the allowable range of the dose or the allowable range of the focus value. Information indicating which of the allowable range of the dose and the allowable range of the focus value is used as the index is acquired by the data acquisition unit 211.

Hereinafter, when the allowable range of the dose and the allowable range of the focus value are not distinguished, the allowable range of the dose and the allowable range of the focus value may be referred to as “exposure margin”.

An allowable range of influence on the optical image can be designated by providing a threshold value for the exposure margin. Thus, a magnitude of the influence on the optical image can be determined with determination as to whether the exposure margin based on each piece of design information of the candidates of the pattern of the repair film exceeds the threshold value.

The selection unit 214 selects design information in which the exposure margin exceeds a first threshold value among design information of one or more candidates of the pattern of the repair film based on the exposure margin calculated by the calculation unit 213. Specifically, the selection unit 214 determines whether design information in which at least one of the allowable range of the dose or the allowable range of the focus value exceeds the first threshold value exists among the design information of the one or more candidates of the pattern of the repair film. As a result, it is possible to obtain the design information of the candidate of the pattern of the repair film in which influence on the optical image is allowable.

When design information in which the exposure margin exceeds the first threshold value exists, the selection unit 214 selects design information having the largest exposure margin. Specifically, when the allowable range of the dose is designated as the index for determining whether an influence occurs on the optical image, the selection unit 214 selects design information having the largest allowable range of the dose. Meanwhile, for example, when the allowable range of the focus value is designated as the index for determining whether an influence occurs on the optical image, the selection unit 214 selects design information having the largest allowable range of the focus value.

When there is one piece of design information in which the exposure margin exceeds the first threshold value, the selection unit 214 selects the one piece of design information. When there are two or more pieces of design information in which the exposure margin exceeds the first threshold value, the selection unit 214 selects the design information having the largest exposure margin from among the two or more pieces of design information. As a result, it is possible to obtain the design information of the pattern of the repair film having a smaller influence on the optical image.

The repair unit 220 forms the pattern of the repair film on the transfer pattern 10 based on the design information selected by the selection unit 214. Thus, the pattern defect 23 is repaired. The pattern of the repair film can be formed, for example, by imprinting source gas of the repair film on the transfer pattern 10 by a charged particle beam. As a result, the pattern of the repair film of a dimension and a shape having a smaller influence on the optical image can be formed on the transfer pattern 10.

The determination unit 215 of the repair pattern generation unit 210 determines whether the pattern defect 23 is successfully repaired based on the optical image acquired by the optical image acquisition device 300 described below.

The determination unit 215 also determines whether the pattern defect 23 is repairable by the repair film based on the image of the pattern defect 23 acquired by the data acquisition unit 211. Specifically, the determination unit 215 determines whether repair can be performed based on the size of the pattern defect 23 and the number of the pattern defects 23 in the image of the pattern defect 23. For example, when plural pattern defects 23 are present in the image of the pattern defect 23 or when the pattern defect 23 exceeds a predetermined size, the determination unit 215 determines that the pattern defect 23 cannot be repaired by the repair film, and otherwise, determines that the pattern defect 23 is repairable by the repair film.

The optical image acquisition device 300 acquires an optical image of the transfer pattern 10 on which the repair film is formed. Information including the acquired optical image is transmitted to the determination unit 215 of the repair pattern generation unit 210.

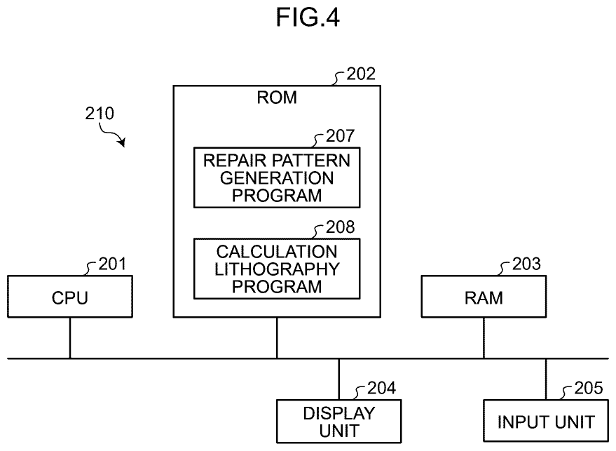

FIG. 4 is a diagram illustrating an example of a hardware configuration of the repair pattern generation unit 210 according to the embodiment.

As illustrated in FIG. 4, the repair pattern generation unit 210 includes a central processing unit (CPU) 201, a read only memory (ROM) 202, a random access memory (RAM) 203, a display unit 204, and an input unit 205. The CPU 201, the ROM 202, the RAM 203, the display unit 204, and the input unit 205 in the repair pattern generation unit 210 are connected via a bus line.

The ROM 202 stores a repair pattern generation program 207 and a calculation lithography program 208 that are computer programs. The ROM 202 is an example of a non-transitory tangible computer-readable storage medium. The repair pattern generation program 207 and the calculation lithography program 208 may be configured to be provided as files in an installable format or an executable format recorded in a non-transitory tangible computer readable recording medium such as a compact disc-read only memory (CD-ROM), a flexible disc (FD), a CD-recordable (CD-R), a digital versatile disk (DVD), a universal serial bus (USB) memory, or a secure digital (SD) card. The repair pattern generation program 207 and the calculation lithography program 208 stored in the ROM 202 are loaded into the RAM 203 via the bus line.

The repair pattern generation program 207 can execute the entire pattern repair process, and the calculation lithography program 208 can execute the electromagnetic field calculation in the pattern repair process based on the design information of the candidate of the pattern of the repair film. The repair pattern generation program 207 and the calculation lithography program 208 are computer program products having a computer-readable recording medium including a plurality of computer-executable instructions for performing the pattern repair process and the electromagnetic field calculation. In the repair pattern generation program 207 and the calculation lithography program 208, the instructions cause a computer to execute the pattern repair process and the electromagnetic field calculation.

The CPU 201 executes each program loaded into the RAM 203. Specifically, for example, in the pattern repair process, the CPU 201 reads the repair pattern generation program 207 from the ROM 202, loads the program into a program storage area in the RAM 203, and executes various processes in accordance with an instruction input from the input unit 205 by the user.

The display unit 204 is a display device such as a liquid crystal monitor and displays, for example, the design information selected by the selection unit 214 or the like based on an instruction from the CPU 201. The input unit 205 includes a mouse and a keyboard and inputs instruction information (design information of the candidate of the pattern of the repair film, and the like) input from the user. The instruction information input to the input unit 205 is transmitted to the CPU 201.

The repair pattern generation program 207 and the calculation lithography program 208 executed by the repair pattern generation unit 210 have, for example, a module configuration including the calculation unit 213 and the like, are loaded into a main storage device, and are generated on the main storage device.

Each of the data acquisition unit 211, the film thickness determination unit 212, the calculation unit 213, the selection unit 214, and the determination unit 215 of the repair pattern generation unit 210 in FIG. 3 described above may be implemented by the CPU 201 executing each program or may be implemented by a dedicated hardware circuit.

Note that the calculation lithography program 208 may be stored in a computer or the like different from the repair pattern generation unit 210.

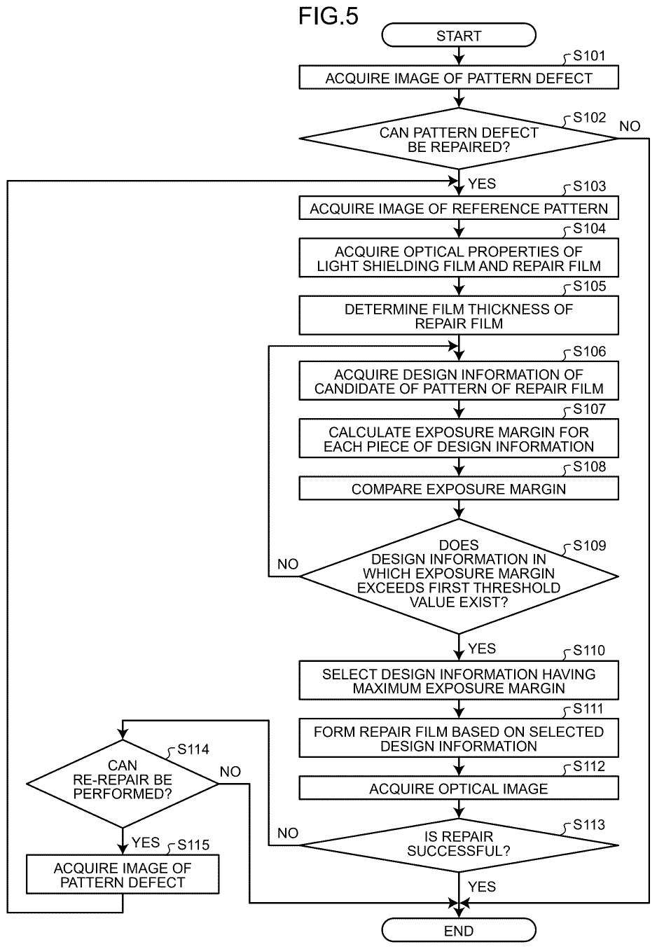

Next, a procedure of the pattern repair process executed in the pattern repair device 200 is described with reference to FIGS. 5 to 9.

FIG. 5 is a flowchart illustrating an example of the procedure of the pattern repair process according to the embodiment.

Prior to step S101, an image of the transfer pattern 10 is captured in the defect detection device 100 and the pattern defect 23 is detected.

The data acquisition unit 211 acquires the image of the pattern defect 23 detected by the defect detection device 100 (step S101).

The determination unit 215 determines whether the pattern defect 23 is repairable based on the image of the pattern defect 23 (step S102). When the determination unit 215 determines that the pattern defect 23 cannot be repaired (step S102: No), the process ends. Meanwhile, when the determination unit 215 determines that the pattern defect 23 is repairable (step S102: Yes), the data acquisition unit 211 acquires, for example, the image of the reference pattern from the ROM 202 (step S103). The determination unit 215 determines whether the pattern defect 23 is repairable based on the size and the number of the pattern defects 23 in the image of the pattern defect 23.

The data acquisition unit 211 acquires the optical properties of the light shielding film 12 and the optical properties of the repair film (step S104).

The film thickness determination unit 212 determines the film thickness of the repair film based on the optical properties of the light shielding film 12 and the repair film (step S105). The film thickness determination unit 212 determines the film thickness of the repair film such that the optical properties of the pattern of the repair film are substantially equal to the optical properties of the light shielding film 12 in the light shielding forming part 21. The film thickness of the pattern of the repair film determined by the film thickness determination unit 212 is, for example, T2 (T2>T1).

The data acquisition unit 211 acquires one or more pieces of design information of the candidate of the pattern of the repair film based on the images of the pattern defect 23 and the reference pattern (step S106).

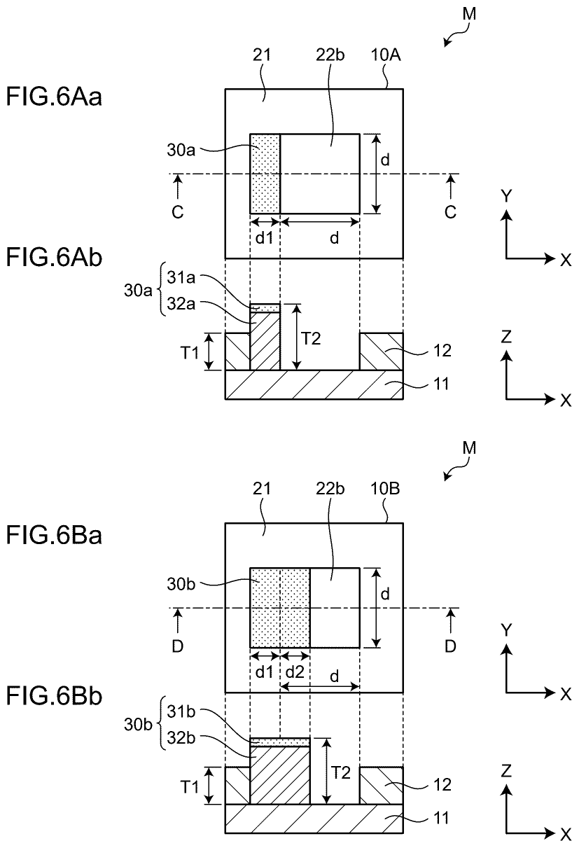

FIG. 6Aa, 6Ab, 6Ba, and 6Bb are diagrams illustrating an example of the design information of the candidate of the pattern of the repair film according to the embodiment.

FIG. 6Aa and 6Ab are diagrams illustrating design information of a candidate 30a of the pattern of the repair film and a configuration of the transfer pattern 10A when the candidate 30a of the pattern of the repair film is formed. FIG. 6Ba and 6Bb are diagrams illustrating design information of a candidate 30b of the pattern of the repair film and a configuration of a transfer pattern 10B when the candidate 30b of the pattern of the repair film is formed. FIG. 6Aa and 6Ba are plan views of the photomask M each including each of the transfer patterns 10A and 10B, and FIG. 6Ab and 6Bb are cross-sectional views taken along each of lines CC and DD in FIG. 6Aa and 6Ba.

As illustrated in FIG. 6Aa and 6Ab, the candidate 30a of the pattern of the repair film is a pattern formed at a position corresponding to the pattern defect 23 (FIG. 1Ba and 1Bb). The candidate 30a of the pattern of the repair film has a rectangular shape in which the length of one side in the X direction is “d1” and the length of one side in the Y direction is “d”. By forming the candidate 30a of the pattern of the repair film, the light transmitting part 22b of the transfer pattern 10A has a square shape in which the length of one side is “d”.

The film thickness of the candidate 30a of the pattern of the repair film is “T2” and is larger than the film thickness “T1” of the light shielding film 12. The candidate 30a of the pattern of the repair film has a configuration in which a chromium film 31a is stacked on a TEOS film 32a.

As illustrated in FIG. 6Ba and 6Bb, the candidate 30b of the pattern of the repair film is a pattern excessively (largely) formed by “d2” in the positive X direction from the position corresponding to the pattern defect 23 (FIG. 1Ba and 1Bb). The candidate 30b of the pattern of the repair film has a rectangular shape in which the length of one side in the X direction is “d1+d2” and the length of one side in the Y direction is “d”. By forming the candidate 30b of the pattern of the repair film, the light transmitting part 22b of the transfer pattern 10B has a rectangular shape in which the length of one side in the X direction is “d−d2” and the length of one side along the Y direction is “d”, that is, a shape having a long side along the Y direction.

The film thickness of the candidate 30b of the pattern of the repair film is “T2” and is larger than the film thickness “T1” of the light shielding film 12. The candidate 30b of the pattern of the repair film has a configuration in which a chromium film 31b is stacked on a TEOS film 32b.

Note that the design information of the candidates 30a and 30b of the pattern of the repair film illustrated in FIG. 6Aa to 6Bb is merely an example and the embodiment is not limited thereto.

The calculation unit 213 performs the electromagnetic field calculation using the film thickness information of the candidates 30a and 30b of the pattern of the repair film and calculates the exposure margin for the design information of each of the candidates 30a and 30b of the pattern of the repair film (step S107). Specifically, the calculation unit 213 calculates the exposure margin for the optical image of each of the transfer pattern 10A in which the candidate 30a of the pattern of the repair film is formed and the transfer pattern 10B in which the candidate 30b of the pattern of the repair film is formed. The calculation unit 213 also calculates the exposure margin for the optical image of the reference pattern for comparison.

The calculation unit 213 calculates the exposure margin for each of the reference pattern and the transfer patterns 10A and 10B described above in accordance with an instruction of the calculation lithography program 208.

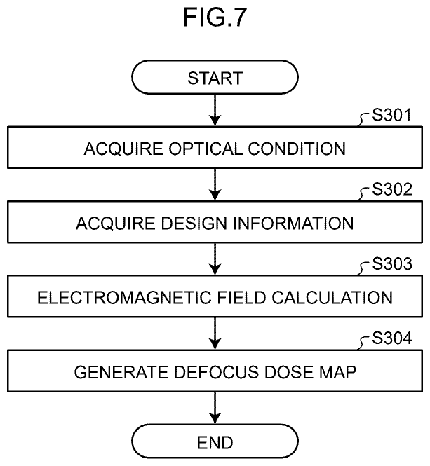

FIG. 7 is a diagram illustrating a procedure of a process of the calculation lithography program 208 according to the embodiment. The process of the calculation lithography program 208 is a process for calculating the exposure margin by electromagnetic field calculation. The process by the calculation lithography program 208 is performed as part of the pattern repair process.

The calculation unit 213 acquires information including optical conditions necessary for calculating the exposure margin (step S301). For example, the calculation unit 213 acquires information such as an exposure wavelength, presence/absence of performing immersion exposure, a dose and a focus range to be calculated, and a resist type (positive or negative). The calculation unit 213 acquires such information through an input by the user, for example, via the input unit 205.

The calculation unit 213 acquires the design information of each of the reference pattern and the transfer patterns 10A and 10B (step S302). The design information of the transfer pattern 10A includes the design information of the candidate 30a of the pattern of the repair film, and the design information of the transfer pattern 10B includes the design information of the candidate 30b of the pattern of the repair film.

The calculation unit 213 performs the electromagnetic field calculation for each of the acquired reference pattern and transfer patterns 10A and 10B (step S303). Specifically, the calculation unit 213 performs the electromagnetic field calculation using the film thickness information of each of the candidates 30a and 30b of the pattern of the repair film.

As a method of the electromagnetic field calculation, the calculation unit 213 may use, for example, a finite difference time domain method using a region around the pattern defect 23 as a calculation region or a rigorous coupled wave analysis method. By such methods, an exact solution can be obtained. As another method of the electromagnetic field calculation, the calculation unit 213 may use, for example, a calculation method using an approximate mask three-dimensional model such as a boundary layer model, a region division method, a filter-based method, a machine learning method, or a deep learning method in which a region around the pattern defect 23 is used as a calculation region. By such methods, a calculation speed of the electromagnetic field calculation can be increased.

The calculation unit 213 generates a defocus dose map based on the result of the electromagnetic field calculation (step S304). Specifically, the calculation unit 213 generates a defocus dose map of the optical image in each of the reference pattern and the transfer patterns 10A and 10B.

The defocus dose map includes information indicating transition of dimensions (optical images) of the patterns formed on the semiconductor substrate at different doses and different focus values. The calculation unit 213 calculates the exposure margin in accordance with the defocus dose map. The calculated exposure margin reflects the film thickness information of each of the candidates 30a and 30b of the pattern of the repair film.

As described above, the process of the calculation lithography program 208 ends. Note that the calculation unit 213 may acquire the defocus dose map of the optical image of the reference pattern from a database or the like.

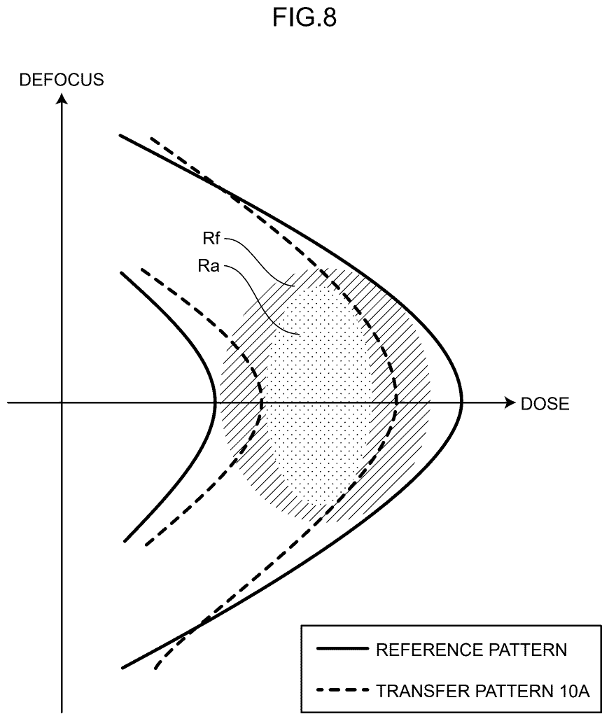

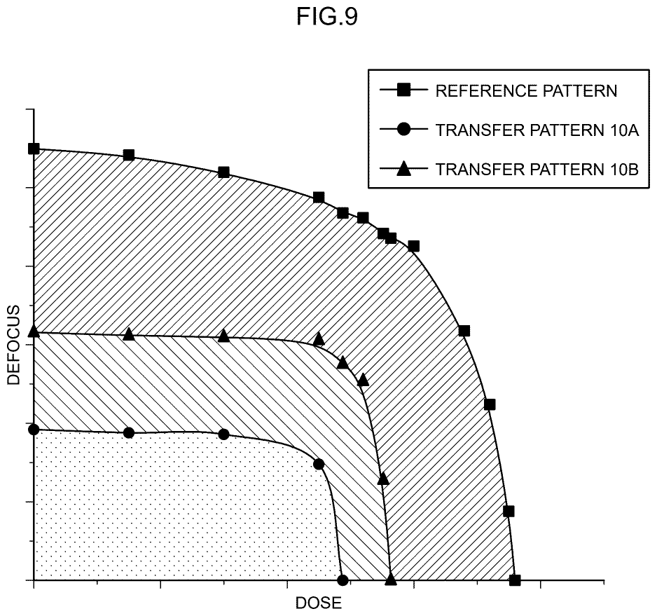

FIGS. 8 and 9 illustrate examples of calculation results of the exposure margin. FIGS. 8 and 9 are obtained in practice by experiments.

FIG. 8 is a diagram illustrating an example of the calculation result of the exposure margin according to the embodiment. In FIG. 8, a horizontal axis corresponds to the dose, and a vertical axis corresponds to the focus value.

FIG. 8 illustrates allowable ranges of the focus value and the dose with which a dimension in a range of ±10% of a target dimension can be obtained on the semiconductor substrate. Allowable ranges Rf and Ra illustrated in FIG. 8 are each examples of the exposure margin.

In FIG. 8, solid lines depict the defocus dose map of the reference pattern, and broken lines depict the defocus dose map of the transfer pattern 10A. A region between the two solid lines indicates the allowable range Rf of the reference pattern, and a region between the two broken lines indicates the allowable range Ra of the transfer pattern 10A.

An area of the allowable range Ra of the transfer pattern 10A is less than half of an area of the allowable range Rf of the reference pattern. This means that the exposure margin for the transfer pattern 10A is greatly reduced compared to the reference pattern. It can be seen from FIG. 8 that, when the pattern of the repair film is formed based on the design information of the candidate 30a of the pattern of the repair film, a light intensity distribution is significantly deteriorated, namely, bad influence occurs on the optical image.

FIG. 9 is a diagram illustrating another example of the calculation result of the exposure margin according to the embodiment. In FIG. 9, a horizontal axis corresponds to the dose, and a vertical axis corresponds to the focus value.

FIG. 9 is obtained by changing a display manner from FIG. 8. In FIG. 9, a maximum focus value in the allowable ranges Rf and Ra is illustrated for each dose. The maximum focus value (allowable range of the focus value) at each dose illustrated in FIG. 9 is an example of the exposure margin. The maximum dose (allowable range of the dose) at each focus value is an example of the exposure margin.

In FIG. 9, a solid line connecting black square plots indicates the exposure margin for the reference pattern, a solid line connecting black circle plots indicates the exposure margin for the transfer pattern 10A, and a solid line connecting black triangle plots indicates the exposure margin for the transfer pattern 10B.

As illustrated in FIG. 9, for example, the maximum focus values of the reference pattern and the transfer patterns 10A and 10B at each dose decrease in the order of the reference pattern, the transfer pattern 10B, and the transfer pattern 10A. Specifically, when the maximum focus value of the optical image of the reference pattern at a predetermined dose is 100%, the maximum focus value for the transfer pattern 10A is 30% to 40%, and the maximum focus value for the transfer pattern 10B is 50% to 60%. It can be seen from FIG. 9 that, by forming the pattern of the repair film based on the design information of the candidate 30b of the pattern of the repair film instead of the candidate 30a of the pattern of the repair film, deterioration of the light intensity distribution can be reduced, that is, an influence on the optical image can be reduced.

In the present embodiment, the first threshold value is, for example, 50% when each of the maximum dose and the maximum focus value of the reference pattern is 100%.

The selection unit 214 (FIG. 5) compares the exposure margin for the reference pattern calculated by the calculation unit 213 with each exposure margin for the design information of the candidate of the pattern of the repair film (step S108), and determines whether design information in which the exposure margin exceeds 50% as the first threshold value exists (step S109). Specifically, the selection unit 214 compares the maximum dose at the predetermined focus value and the maximum focus value at the predetermined dose for each of the reference pattern, the transfer patterns 10A and 10B, and determines whether design information in which at least one of the maximum dose or the maximum focus value exceeds 50% exists.

When the selection unit 214 determines that design information in which the exposure margin exceeds 50% exists (step S109: Yes), the selection unit 214 selects the design information having the largest exposure margin (step S110).

Specifically, when the maximum dose (allowable range of the dose) at a predetermined focus value is designated as an index for determining whether an influence occurs on the optical image, the selection unit 214 selects the design information having the largest maximum dose. For example, in FIG. 9, the maximum dose of the transfer pattern 10A is 65% and the maximum dose of the transfer pattern 10B is 75% at a predetermined focus value. The selection unit 214 selects the design information of the transfer pattern 10B having the largest maximum dose.

Meanwhile, when the maximum focus value (allowable range of the focus value) at a predetermined dose is designated as an index for determining whether an influence occurs on the optical image, the selection unit 214 selects the design information having the largest maximum focus value. Although an example is omitted, the selection unit 214 selects the design information having the largest maximum focus value at a predetermined dose from the transfer patterns 10A and 10B.

As described above, the design information of the transfer pattern 10B includes the design information of the candidate 30b of the pattern of the repair film. Thus, the selection unit 214 selects the design information of the candidate 30b of the pattern of the repair film. As such, it is possible to obtain the design information of the candidate of the pattern of the repair film capable of reducing an influence on the optical image among the candidates 30a and 30b of the pattern of the repair film.

Meanwhile, for example, when the selection unit 214 determines that design information in which the exposure margin exceeds the first threshold value does not exist (step S109: No), the process returns to step S106.

The repair unit 220 forms the pattern of the repair film on the transfer pattern 10 based on the design information selected by the selection unit 214 (step S111). For example, the repair unit 220 forms the pattern of the repair film on the transfer pattern 10 based on the design information of the candidate 30b of the pattern of the repair film. As such, it is possible to obtain the pattern of the repair film capable of reducing an influence on the optical image.

When forming the pattern of the repair film, the repair unit 220 first carries the photomask M on which the repair film is to be formed into a vacuum processing layer and determines the position of the pattern defect 23 by performing positional alignment. After designating the film type of the repair film, the repair unit 220 forms the repair film based on the design information of the candidate 30b of the pattern of the repair film. Thus, the pattern defect 23 is repaired. After observing a formation part of the repair film, the repair unit 220 carries the photomask M out from the vacuum processing layer. The photomask M carried out from the repair unit 220 is carried into the optical image acquisition device 300.

The repair unit 220 determines whether the repair is successful based on the observation result of the formation part of the repair film. Specifically, the repair unit 220 determines whether the repair film corresponding to the design information of the candidate 30b of the pattern of the repair film is formed based on the image automatically acquired by observing the formation part of the repair film. For example, in response to determining that the repair film corresponding to the design information of the candidate 30b of the pattern of the repair film is not formed, the repair unit 220 may end the pattern repair process without carrying the photomask M into the optical image acquisition device 300 since the repair unit 220 does not function or the like. For example, when the repair unit 220 determines that the repair film corresponding to the design information of the candidate 30b of the pattern of the repair film is not formed, the repair film may be formed again. At this time, the film type of the repair film may be changed.

In order to determine whether the repair is successful, the optical image acquisition device 300 acquires the optical image of the transfer pattern 10 on which the pattern of the repair film is formed (step S112). The optical image acquisition device 300 transmits information including the optical image to the determination unit 215 of the repair pattern generation unit 210.

The determination unit 215 determines whether the repair of the pattern defect 23 is successful based on the optical image acquired by the optical image acquisition device 300 (step S113). Specifically, the determination unit 215 compares the exposure margin for the candidate 30b of the pattern of the repair film calculated in step S107 with the exposure margin based on the optical image acquired by the optical image acquisition device 300 and determines whether the difference between the exposure margins is less than a second threshold value.

When the determination unit 215 determines that the difference in the exposure margin is less than the second threshold value, that is, the repair is successful (step S113: Yes), the pattern repair process of the embodiment ends.

Meanwhile, when the determination unit 215 determines that the difference in the exposure margin is greater than or equal to the second threshold value, namely, the repair is not successful (step S113: No), the determination unit 215 next determines whether the photomask M can be re-repaired (step S114).

When the difference between the exposure margin for the candidate 30b of the pattern of the repair film and the exposure margin based on the optical image acquired by the optical image acquisition device 300 does not exceed a third threshold value (third threshold value >second threshold value), the determination unit 215 determines that re-repair can be performed (step S114: Yes), and the process proceeds to step S115. Thereafter, the photomask M is carried into the defect detection device 100, and the image of the pattern defect is captured. The data acquisition unit 211 acquires the image of the pattern defect captured by the defect detection device 100 (step S115), and the process proceeds to step S103.

When the difference between the exposure margin for the candidate 30b of the pattern of the repair film and the exposure margin based on the optical image acquired by the optical image acquisition device 300 is equal to or larger than the second threshold value and equal to or smaller than the third threshold value, the determination unit 215 determines that re-repair cannot be performed since the repair unit 220 does not function or the like (step S114: No), and the pattern repair process of the embodiment ends.

Note that the determination unit 215 may determine whether the repair is successful based on the exposure margin calculated using the calculation lithography program 208 instead of the exposure margin based on the optical image acquired by the optical image acquisition device 300. Then, the shape of the transfer pattern 10 after repair acquired by observing the formation part of the repair film by the repair unit 220 in step S111 may be used for the calculation of the exposure margin using the calculation lithography program 208.

### Overview

There may be a case that the film thickness information of the pattern of the repair film is not considered in the electromagnetic field calculation. In such a case, the exposure margin is calculated based on two-dimensional design information of the pattern of the repair film. Therefore, it is difficult to accurately measure an influence on the optical image caused by the pattern of the repair film.

In contrast, according to the pattern repair method and the pattern repair device 200 of the embodiment, the exposure margin is calculated by the electromagnetic field calculation using the film thickness information of the repair film. Therefore, even when, for example, the film thickness of the pattern configured by the light shielding film 12 is different from the film thickness of the pattern of the repair film, an influence on the optical image caused by the pattern of the repair film can be measured with higher accuracy. As a result, the accuracy of pattern design using the ILT technology can be improved.

In the pattern repair method and the pattern repair device 200 of the embodiment, the design information in which the exposure margin exceeds the threshold value is selected from the design information of the candidate of the pattern of the repair film. As a result, it is possible to obtain the design information of the pattern of the repair film having a smaller influence on the optical image. According to the pattern repair method and the pattern repair device 200 of the embodiment, it is possible to reduce an influence on the optical image caused by the pattern of the repair film.

### Other Embodiments

In the above-described embodiment, the data acquisition unit 211 acquires the design information of the candidate in which the dimension of the light transmitting part 22b in the X direction is different as the candidate of the pattern of the repair film, but the shape of the candidate of the pattern of the repair film is not limited thereto. For example, the data acquisition unit 211 may acquire design information of a candidate having a shape in which the dimension of a diagonal line of the light transmitting part 22b is different, or may acquire, for example, design information of a candidate having a shape in which a distance from a center position of the light transmitting part 22b is different.

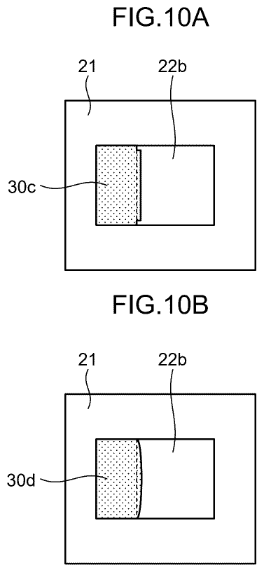

In the above-described embodiment, the data acquisition unit 211 acquires the design information of the candidate of the pattern of the repair film formed in the rectangular shape, but the shape of the candidate of the pattern of the repair film is not limited thereto. The candidate of the pattern of the repair film may have, for example, a shape as illustrated in FIGS. 10A and 10B.

FIGS. 10A and 10B are diagrams illustrating another example of the design information of a candidate of a pattern of a repair film according to the embodiment.

As illustrated in FIG. 10A, a candidate 30c of a pattern of a repair film may have a shape with few corners. Alternatively, as illustrated in FIG. 10B, a candidate 30d of a pattern of a repair film may have a curved contour. The data acquisition unit 211 can acquire candidates of the pattern of the repair film having various shapes such as illustrated in FIGS. 10A and 10B.

While certain embodiments have been described, these embodiments have been presented by way of example only, and are not intended to limit the scope of the inventions. Indeed, the novel embodiments described herein may be embodied in a variety of other forms; moreover, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern repair method comprising:
executing a first operation including
acquiring information about a defect in a pattern of a light shielding film in a photomask, and
acquiring optical properties of the light shielding film and optical properties of a repair film for repairing the defect;
executing a second operation including determining a film thickness of the repair film based on the optical properties of the light shielding film and the optical properties of the repair film;
executing a third operation including acquiring one or more pieces of design information indicating a dimension and a shape of a candidate of a pattern of the repair film, the one or more pieces of design information including film thickness information indicating the film thickness of the repair film;
executing a fourth operation including calculating an exposure margin for each of the one or more pieces of design information by electromagnetic field calculation using the film thickness information of the repair film;
executing a fifth operation including selecting a piece of design information corresponding to the exposure margin exceeding a threshold value from among the one or more pieces of design information; and
executing a sixth operation including forming the repair film in the photomask in accordance with the selected piece of design information.

2. The pattern repair method according to claim 1, wherein
the fourth operation is executed by calculating, as the exposure margin, an allowable range of a dose and an allowable range of a focus value for obtaining a target optical image, and
the fifth operation is executed by selecting a piece of design information corresponding to at least one of the allowable range of the dose or the allowable range of the focus value being the largest from among the one or more pieces of design information.

3. The pattern repair method according to claim 1, wherein
the one or more pieces of design information acquired in the third operation are two or more pieces of design information, and
the fifth operation is executed by selecting a piece of design information corresponding to the largest exposure margin from among the two or more pieces of design information.

4. The pattern repair method according to claim 1, wherein
the light shielding film includes a silicon nitride film, and
the repair film includes a multilayer film in which a chromium film is stacked on a TEOS film.

5. The pattern repair method according to claim 1, wherein the optical properties include at least one of a light transmittance or a phase difference of the light shielding film.

6. The pattern repair method according to claim 1, wherein
the first operation further includes
determining whether the defect in the pattern is repairable based on the information about the defect in the pattern, and
acquiring information about a reference pattern having no defect in response to determining that the defect in the pattern is repairable,
the fourth operation further includes calculating an exposure margin for the reference pattern,
the fifth operation further includes
comparing an exposure margin for each of the one or more pieces of design information with the exposure margin for the reference pattern,
determining whether there are pieces of design information each corresponding to the exposure margin exceeding the threshold value from among the one or more pieces of design information, and
selecting a piece of design information corresponding to the largest exposure margin in response to determining that there are the pieces of design information corresponding to the exposure margin exceeding the threshold value, and
the pattern repair method further comprises, after the repair film is formed in the photomask in the sixth operation,
acquiring an optical image of the photomask,
determining whether repair of the defect in the pattern is successful based on an exposure margin for the optical image and the exposure margin for the piece of design information selected in the fifth operation,
determining whether the defect in the pattern is re-repairable in response to determining that the repair of the defect in the pattern is not successful, the determining being executed based on the exposure margin for the optical image and the exposure margin for the design information selected in the fifth operation, and
re-acquiring information about the defect in the pattern in response to determining that the piece of defect in the pattern is re-repairable.

7. A pattern repair device comprising:
a memory in which a computer program is stored; and
a hardware processor connected to the memory and configured to perform processing by executing the computer program, the processing including:
executing a first operation including
acquiring information about a defect in a pattern of a light shielding film in a photomask, and
acquiring optical properties of the light shielding film and optical properties of a repair film for repairing the defect;
executing a second operation including determining a film thickness of the repair film based on the optical properties of the light shielding film and the optical properties of the repair film;
executing a third operation including acquiring one or more pieces of design information indicating a dimension and a shape of a candidate of a pattern of the repair film, the one or more pieces of design information including film thickness information indicating the film thickness of the repair film;
executing a fourth operation including calculating an exposure margin for each of the one or more pieces of design information by electromagnetic field calculation using the film thickness information of the repair film;
executing a fifth operation including selecting a piece of design information corresponding to the exposure margin exceeding a threshold value from among the one or more pieces of design information; and
executing a sixth operation including forming the repair film in the photomask in accordance with the selected piece of design information.

8. The pattern repair device according to claim 7, wherein
the exposure margin includes an allowable range of a dose and an allowable range of a focus value for obtaining a target optical image, and
the hardware processor is configured to execute the fifth operation by selecting a piece of design information corresponding to at least one of the allowable range of the dose or the allowable range of the focus value being the largest from among the one or more pieces of design information.

9. The pattern repair device according to claim 7, wherein
the one or more pieces of design information acquired in the third operation are two or more pieces of design information, and
the hardware processor is configured to execute the fifth operation by selecting a piece of design information corresponding to the largest exposure margin from among the two or more pieces of design information.

10. The pattern repair device according to claim 7, wherein
the light shielding film includes a silicon nitride film, and
the repair film includes a multilayer film in which a chromium film is stacked on a TEOS film.

11. The pattern repair device according to claim 7, wherein the optical properties include at least one of a light transmittance or a phase difference of the light shielding film.

12. The pattern repair device according to claim 7, wherein
the first operation further includes
determining whether the defect in the pattern is repairable based on the information about the defect in the pattern, and
acquiring information about a reference pattern having no defect in response to determining that the defect in the pattern is repairable,
the fourth operation further includes calculating an exposure margin for the reference pattern,
the fifth operation further includes
comparing an exposure margin for each of the one or more pieces of design information with the exposure margin for the reference pattern,
determining whether there are pieces of design information each corresponding to the exposure margin exceeding the threshold value from among the one or more pieces of design information, and
selecting a piece of design information corresponding to the largest exposure margin in response to determining that there are the pieces of design information corresponding to the exposure margin exceeding the threshold value, and
the processing to be executed by the hardware processor further includes, after the repair film is formed in the photomask in the sixth operation,
acquiring an optical image of the photomask,
determining whether repair of the defect in the pattern is successful based on an exposure margin for the optical image and the exposure margin for the piece of design information selected in the fifth operation,
determining whether the defect in the pattern is re-repairable in response to determining that the repair of the defect in the pattern is not successful, the determining being executed based on the exposure margin for the optical image and the exposure margin for the design information selected in the fifth operation, and
re-acquiring information about the defect in the pattern in response to determining that the piece of defect in the pattern is re-repairable.

13. A non-transitory tangible computer-readable storage medium in which a computer program is stored, the computer program instructing a computer to execute processing, the processing comprising:
executing a first operation including
acquiring information about a defect in a pattern of a light shielding film in a photomask, and
acquiring optical properties of the light shielding film and optical properties of a repair film for repairing the defect;
executing a second operation including determining a film thickness of the repair film based on the optical properties of the light shielding film and the optical properties of the repair film;
executing a third operation including acquiring one or more pieces of design information indicating a dimension and a shape of a candidate of a pattern of the repair film, the one or more pieces of design information including film thickness information indicating the film thickness of the repair film;
executing a fourth operation including calculating an exposure margin for each of the one or more pieces of design information by electromagnetic field calculation using the film thickness information of the repair film;
executing a fifth operation including selecting a piece of design information corresponding to the exposure margin exceeding a threshold value from among the one or more pieces of design information; and
executing a sixth operation including forming the repair film in the photomask in accordance with the selected piece of design information.

14. The recording medium according to claim 13, wherein
the fourth operation is executed by calculating, as the exposure margin, an allowable range of a dose and an allowable range of a focus value for obtaining a target optical image, and
the fifth operation is executed by selecting a piece of design information corresponding to at least one of the allowable range of the dose or the allowable range of the focus value being the largest from among the one or more pieces of design information.

15. The recording medium according to claim 13, wherein
the one or more pieces of design information acquired in the third operation are two or more pieces of design information, and
the fifth operation is executed by selecting a piece of design information corresponding to the largest exposure margin from among the two or more pieces of design information.

16. The recording medium according to claim 13, wherein
the light shielding film includes a silicon nitride film, and
the repair film includes a multilayer film in which a chromium film is stacked on a TEOS film.

17. The recording medium according to claim 13, wherein the optical properties include at least one of a light transmittance or a phase difference of the light shielding film.

18. The recording medium according to claim 13, wherein
the first operation further includes
determining whether the defect in the pattern is repairable based on the information about the defect in the pattern, and
acquiring information about a reference pattern having no defect in response to determining that the defect in the pattern is repairable,
the fourth operation further includes calculating an exposure margin for the reference pattern,
the fifth operation further includes
comparing an exposure margin for each of the one or more pieces of design information with the exposure margin for the reference pattern,
determining whether there are pieces of design information each corresponding to the exposure margin exceeding the threshold value from among the one or more pieces of design information, and
selecting a piece of design information corresponding to the largest exposure margin in response to determining that there are the pieces of design information corresponding to the exposure margin exceeding the threshold value, and
the processing to be executed by the computer further includes, after the repair film is formed in the photomask in the sixth operation,
acquiring an optical image of the photomask,
determining whether repair of the defect in the pattern is successful based on an exposure margin for the optical image and the exposure margin for the piece of design information selected in the fifth operation,
determining whether the defect in the pattern is re-repairable in response to determining that the repair of the defect in the pattern is not successful, the determining being executed based on the exposure margin for the optical image and the exposure margin for the design information selected in the fifth operation, and
re-acquiring information about the defect in the pattern in response to determining that the piece of defect in the pattern is re-repairable.
